(19) United States
(12) Patent Application Publication
(10) Pub. No.: US 2017/0043501 A1
(43) Pub. Date: Feb. 16, 2017

(54) METHOD OF MANUFACTURE OF MICRO COMPONENTS, AND COMPONENTS FORMED BY SUCH A PROCESS

(71) Applicant: Master Dynamic Limited, Shatin, New Territories (HK)

(72) Inventors: Yingnan WANG, Shatin, New Territories (HK); Jianxing HUANG, Shatin, New Territories (HK)

(21) Appl. No.: 15/306,477

(22) PCT Filed: Apr. 22, 2015
(86) PCT No.: PCT/CN2015/077240

§ 371 Date: Oct. 24, 2016

(30) Foreign Application Priority Data
Apr. 23, 2014 (HK) 14103863.2

(51) Int. Cl. B28D 5/04; C09K 13/08; G03F 7/40

(52) U.S. Cl. CPC B28D 5/04; G03F 7/405; C09K 13/08

(57) ABSTRACT

A method of forming a multi-level component includes the step of forming at least one arrangement of micro trenches in a predetermined arrangement in a mask material by a lithography process. Another step involves applying one or more etching processes to a surface of a component upon which the mask is applied. The micro trenches have either first or second different aspect ratios. In the applying step, the component is etched by an aspect ratio dependent etch (ARDE) process so as to form an arrangement of micro trenches and micro pillars between adjacent micro trenches. Another step involves removing the arrangement of micro pillars from the component by a removal process. There is also a multi-level component made according to the above method with a first portion at a first level and a further portion of a further level different from the first level.

### FIELD OF THE INVENTION

The present invention relates to a method of fabrication of micro components, more particularly for fabrication of multi-level micro components.

### BACKGROUND TO THE INVENTION

Micro components, such as gears and some other mechanical components are often used in the watch industry, as well as in other industrial application including the biomedical engineering field such as in bio-medical devices and the like. Such components may be formed from applicable materials, including silicon.

Due to complexity requirements of such components for such devices and applications thereof, there exists a requirement for multi-level components.

Typically, multi-level components are fabricated by processes including utilisation of multi-coating of photo resist (PR) and multi-etch processes, or may be realised by component assembly.

However, such methods of the prior art have drawbacks and deficiencies, including problems and difficulties associated with alignment during multi-process, in particularly with respect to the multi-coating and multi-etch method.

The amount of time for alignment and etching which is required for such multi-coating and multi-etch methods equates to the number of levels required for forming a multi-level article. For multi-etching methods, each level requires diligent alignment and manipulation by an operator by use of a microscope during the associated photolithography process.

As such due to the multiple alignment events for the formation of such multi-layer articles, and the inevitable generation of a degree of alignment error of at least several microns, a multi-level component resulting from the formation by such a method will result in having aspects of the component whereby there exists a deviation from the original design, in particular due to the cumulative effects with increased number levels of the requisite component.

In addition to the deviation of a component from the original design specifications when formed according to such a method, multi lithography and multi-etching processes also result in low yield efficiency, as well as high associated cost of manufacture.

During assembling of several small components together, surfaces and portions of components are required to be aligned, such that a final multi-level component may be assembled. Components having multiple surfaces having deviation in portion of the surfaces, results in difficulty of assembly, misalignment of components, low yield efficiency, and increased assembly time.

### OBJECT OF THE INVENTION

It is an object of the present invention to provide a method of fabrication of a micro component, for example a micro component formed from silicon or a silicon based material, which at least ameliorates at least some of the deficiencies as associated with those of the prior art.

### SUMMARY OF THE INVENTION

In a first aspect, the present invention provides a method of forming a multi-level component having a first surface portion of a first level and a second surface portion of a second level different to the level of the first level, said method including the steps of:

(i) forming at least one arrangement of micro trenches or an arrangement of micro pillars having a micro trench therebetween in a predetermined arrangement in a mask material by one or more lithography processes, wherein one or more of said micro trenches have a first aspect ratio and one or more of said micro trenches have a second aspect ratio different from said first aspect ratio;

(ii) applying one or more etching processes to a surface of a component upon which said mask is applied, wherein the component is etched by an aspect ratio dependent etch (ARDE) process so as to form an arrangement of micro trenches and micro pillars between adjacent micro trenches;

wherein one or more micro trenches corresponding to the micro trenches of the first aspect ratio is etched a first level from said surface of the component, and,

wherein one or more micro trenches corresponding to the micro trenches of the second aspect ratio is etched at a second level from said surface of the component and at different level to said first level; and

(iii) removing said arrangement of micro pillars from said component by a removal process;

wherein upon removal of said micro pillars a first surface portion is formed at said first level and a second surface portion is formed at said second level, wherein the second surface portion is at a different level to that of the of the first surface portion. In a first embodiment, the arrangement of micro trenches or arrangement of micro pillars having a micro trench therebetween may include a first plurality of micro trenches or micro pillars having a micro trench between adjacent micro pillars, and a second plurality of micro trenches or micro pillars having a micro trench between adjacent micro pillars, and wherein the micro trenches of said first plurality of micro trenches or micro pillars have said first aspect ratio, and wherein the micro trenches of said second plurality of micro trenches or have said second aspect ratio; and wherein upon removal of said first plurality of micro pillars the first surface portion is formed at said first level and upon removal of said second plurality of micro pillars said second surface portion is formed.

The first surface portion and the second surface portion are preferably discrete surface portions from each other and are formed in a non-continuous spatial arrangement with respect to each other.

The arrangement of micro trenches or an arrangement of micro pillars may include a further plurality of micro trenches or micro pillars having a micro trench between adjacent micro pillars, and wherein upon removal of said further plurality of micro pillars a further surface portion is formed at a further level different from the level of the first surface portion and different from the level of the second surface portion.

Preferably, the first surface portion, the second surface portion and the further surface portion are discrete surface portions from each other and are formed in a non-continuous spatial arrangement with respect to each other.

In another embodiment, the first surface portion and the second surface portion may be continuous surface portions and may be formed in a continuous spatial arrangement with respect to each other.

A plurality of arrangements of micro trenches or an arrangement of micro pillars having a micro trench therebetween may be formed, and wherein each of said plurality of micro trenches has a unique aspect ratio, such that a plurality of surface portions is formed in said component, and wherein said plurality of surface portions are formed in a continuous spatial arrangement with respect to each other and with first surface portion and with said second surface portion.

The plurality of surface portions and said first surface portion and said second surface portion may collectively form a linear surface. Alternatively, plurality of surface portions and said first surface portion and said second surface portion collectively form a non-linear surface.

In embodiments of the invention, the width of micro trenches or diameter of micro pillars of said first aspect ratio formed in said mask material are preferably less than 10 □m, and wherein the width of micro trenches of said second aspect ratio formed in said mask material is less than 10 μm. The lithography process may be UV lithography, laser lithography, electron beam lithography, x-ray lithography, chemical lithography or a combination thereof.

Preferably, the etching process is deep reactive ion etching (DRIE).

Alternatively, the etching process may be reactive ion etching (RIE) or inductively coupled plasma (ICP) etching.

In an embodiment of the invention, the mask may be a photoresist, and the at least one arrangement of micro trenches or an arrangement of micro pillars having a micro trench therebetween in a predetermined arrangement may be formed after application of the mask to the component.

Alternatively, the mask may be a hard mask, and the at least one arrangement of micro trenches or an arrangement of micro pillars having a micro trench therebetween in a predetermined arrangement is formed in the mask prior to application of the mask to the component. The hard mask may be formed from materials including oxidized silicon, or metal or metal allow based materials, polymeric materials, or the like.

The removal process for removal of said micro pillars from said component may include a thermal oxidation process. The removal of said micro pillars may further include applying a chemical etching process for removal of said micro pillars from said component. The thermal oxidation process may be a dry oxygen process, a wet oxygen, or a combination thereof. In an embodiment of the invention, the component may be formed from a silicon or silicon-based material, and the chemical etching process may be a hydrogen fluoride (HF) treatment process. The hydrogen fluoride (HF) treatment process may effected with a concentration in the range of from 1% to 49%.

In another embodiment of the invention, the component may be formed from Gallium arsenide (GaAs), and the chemical etching process may be a Phosphoric acid (H₃PO₄) treatment process.

In other embodiments, the component may be formed form a gemstone material including diamond, pearl, sapphire, synthetic sapphire or the like.

The component may be a micro component, and may be multi-level component provided as a mechanical device component, and may be a mechanical timepiece component.

In a second aspect, the present invention provides a multi-level component having first portion of a first level and a further portion of a further level different to the level of the first portion, wherein said multi-level component is formed according to a method of the foist aspect.

The multi-level component may be a mechanical device component, and may a mechanical timepiece component.

Alternatively, the multi-level component may be a biomedical device component The multi-level component is preferably formed from a silicon or silicon-based material.

Alternatively, the multi-level component many be formed form a gemstone material including diamond, pearl, sapphire, synthetic sapphire or the like.

### BRIEF DESCRIPTION OF THE DRAWINGS

Embodiments and particulars of the present invention will now be described by way of example only and with reference to the accompanying drawings, in which:

FIG. 1a is exemplary schematic representations of an embodiment of a component having multiple surfaces in accordance with the present invention;

FIG. 1b is exemplary schematic representations of a further embodiment of a component having multiple surfaces in accordance with the present invention;

FIG. 2a schematically depicts the effect of aspect ratio dependent etching (ARDE) using deep reactive ion etching (DRIE) showing etching depth variation as a function of aspect ratio;

FIG. 2b shows the sequential etching rate variation with aspect ratio in relation to FIG. 2a;

FIG. 3 depicts the effect of micro loading on etching rate;

FIG. 4a is a schematic depiction of a mask for use in etching in accordance with the present invention;

FIG. 4b is a schematic depiction of a silicon component when etched utilising the mask of FIG. 4a in the process of the present invention;

FIG. 4c is a schematic depiction of the silicon component of FIG. 4b when oxidized in the process of the present invention;

FIG. 4d is a schematic depiction of a silicon component of FIG. 4c when chemically etched utilising in the process of the present invention;

FIG. 5a is a photographic representation of a component having multiple surfaces formed in accordance with the present invention; and

FIG. 5b is an enlarged photographic representation of a portion of the component as depicted in FIG. 5a.

### DETAILED DESCRIPTION OF THE CERTAIN PREFERRED EMBODIMENT

The present invention ulitises non-uniformity in an etching process so as to generate micro trenches in a portion of a component or material and thus generate micro pillars between micro trenches. The formed micro pillars are subsequently removed from the component or material to form a surface or surface portion, and the depth and location of the micro trenches formed determine the geometry and location of such a surface or surface portion.

By utilising non-uniformity in an etching process, multiple surfaces may be formed on a micro component, by varying the location, size and depth of micro trenches formed.

The present invention provides for forming a plurality of micro trenches, utilising aspect dependent ratio etching (ADRE) by lithography techniques, which allows aspect ratio to be utilised to define the depth and location for the formation of micro trenches and upon removal of micro pillars formed during such etching, a requisite surface at a requisite location is formed.

Thus, by controlling the parameters of the ARDE process, the present invention allows micro trenches of differing depths to be formed at different locations and in a single step which define the position and geometry of surfaces to be formed upon removal of the associated micro pillars by a removal process.

Accordingly, the present invention does not require any alignment step between the formation of each surface when forming multiple surface multiple surfaces, as multiple surfaces are formed at the same time as each other in a single process step.

In preferred embodiments of the invention, micro-components formed from silicon or silicon based materials are applicable for providing multiple levels thereon in accordance with the process of the present invention.

Silicon as a material, which is known to be utilised in the semiconductor industry, has been demonstrated to have some applicability in some aspects of the micro or nano-electrical mechanical systems (MEMS/NEMS) field. In embodiments whereby a micro component is formed from a silicon or silicon based material, a multi-level silicon component may be provided whereby the removal of the micro pillars formed may include a post etch oxidation and treatment in HF solution process.

The present invention provides for the formation of multiple level surfaces in a micro component, and those skilled in the art will understand and appreciate that surfaces as provided by the present invention need not necessarily be parallel or of a flat planar form. Furthermore, as will be understood, a surface may be formed from two or more other surfaces, such as when a plurality of sub-surfaces are provided adjacent to each other and in a continuous arrangement, so as to form a larger surface, which may be inclined in one or more planes, or curved in one or more planes.

Accordingly, the present invention provides for a single step etch process for the formation of multiple surfaces, transition surfaces, and complex surfaces, without the necessity of any alignment process between sequential surface etching, in contrast to the prior art, thus obviating at least alignment related issues

The utilisation of variation of ADRE on etch depth allows for multiple surfaces to be formed and provided on a micro component, and the sizing and geometry of recesses defining micro pillars or micro trenches in a mask material which is used so as to provide the ADRE process defines the resultant depth or height of such micro pillars or micro trenches and hence defines the requisite disparity in the level of the portions of the component. According, the distance between the notches is predetermined and incorporated into the designed pattern on a mask material.

By setting the width of the micro pillars or micro trenches in the order of several microns, for example 5 μm, the material of the component which defines the micro pillars or micro trenches may be readily removed.

As will be understood by those skilled in the art, various lithography processes may be utilised in accordance with the invention, including UV or photolithography, e laser lithography, electron beam lithography, x-ray lithography, chemical lithography or a combination thereof.

In accordance with the invention, a suitable mask material may be utilised, and the mask may have micro trenches or micro pillars formed therein, either before application of the mask to the micro component, or after application of the mask material to the micro component.

For applications for example whereby UV or photolithography processes or other applicable lithography processes are utilised, typically a mask formed by a photoresist is applicable, and micro trenches and micro pillars formed after application of the photoresist to the micro components, and the photoresist is applied to the micro component using coating methods as utilised in the art.

In some embodiments, a hard mask may be utilised, whereby a mask is used having pre-etched through or partial through patterns. The material of the micro component to be etched is covered with hard mask, the area of the micro component exposed or partially exposed will be etched away during the etching process. Using such hard masks, the mask material may be formed from materials including oxidized silicon, or metal or metal allow based materials. Alternatively, a hard mask may be formed from a polymeric material, and suitable materials selected which have appropriate resistance to the subsequent process of etching the micro component, so as offer some resistance to plasma etching for example.

It should be understood that during the formation of micro trenches within a mask, the micro trenches need not necessarily extend fully through the depth of the mask, and in embodiments as described, such a mask may be utilised for the formation of micro trenches in a micro component.

Aspect ratio dependence etching (ARDE) effect and micro loading effect are two mechanisms leading to non-uniformity in the etching of silicon using deep reactive ion etching (DRIE) technology, which are phenomena as known and reported in the art. ARDE is effected by charging of a device by incident ions during an etching process. Micro loading is the effect as a result of diffusion limitations in the darkspace region between the glow region and a material to be etched. As known by those in the art, for years those skilled in the art have sought to reduce or eliminate the non-uniformity during DRIE.

By contrast, the present invention utilises non-uniformity effects from ARDE, whilst micro loading effects also play a role.

The non-uniformity effect of DRIE is utilised in the present invention, so as to allow a process and product formed according to such a process, pertaining to multi-level components.

The DRIE process includes a number of process parameters, such as pressure, gas flow rate, radio frequency (RF) power and inductively coupled plasma (ICP) power, and of which influence the result and conduct of such a process.

Aspect ratio dependent etching (ARDE), refers to the phenomenon that the etch rate scales as a result from an etching process do not correlate with absolute feature sizes, but rather with the aspect ratio. Increasing the aspect ratio typically decreases etch rate, whereby such a reduction in etch rate is caused by a reduced transport of reactive species in deep and narrow structures during the etching process.

The present invention, by availing variability of aspect ratio in an ARDE process, allows more complex surface topographies to be provided to a component.

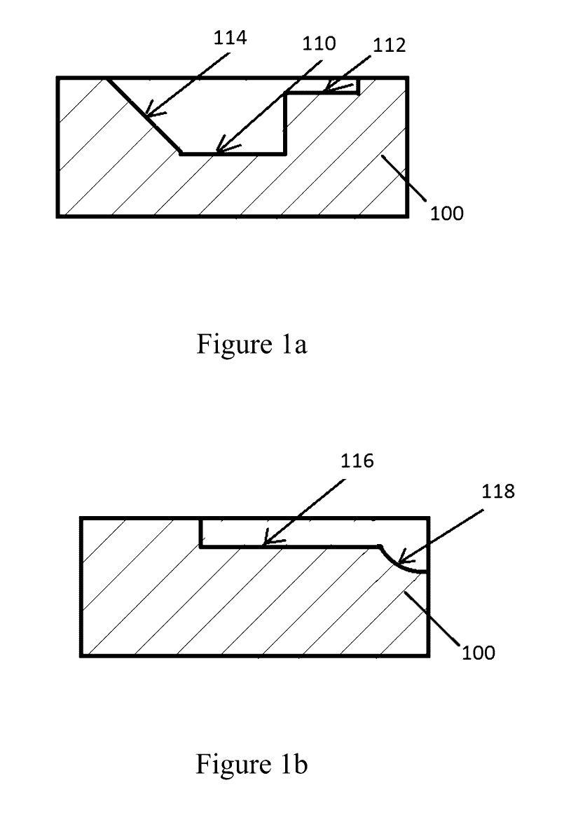

By way of example, exemplary schematic representations of components having multiple surfaces in accordance with the present invention are shown in FIG. 1a and FIG. 1b.

As shown in FIG. 1a, there is depicted a component 100 having a first surface portion 110 and a second surface portion 112, which are at different depths, as formed in accordance with the present invention. A further surface 114 is also depicted, whereby further surface 114 is an inclined surface.

Further surface 114 may be considered as a plurality of surfaces which are provided in a continuous spatial arrangement to each other, such that a single continuous surface 114 is provided.

Referring to FIG. 1b, there is depicted a further schematic exemplary embodiment of a component 100 having a first surface portion 116 which is a planar surface, and also includes a curved surface 118. Curved surface 118 may also be considered as plurality of surfaces which are provided in a continuous spatial arrangement to each other, such that a single continuous surface 118 is provided.

As provided by the present invention, various alternate geometries and combinations may be achieved, with appropriate selection of an arrangement of micro trenches in a mask material.

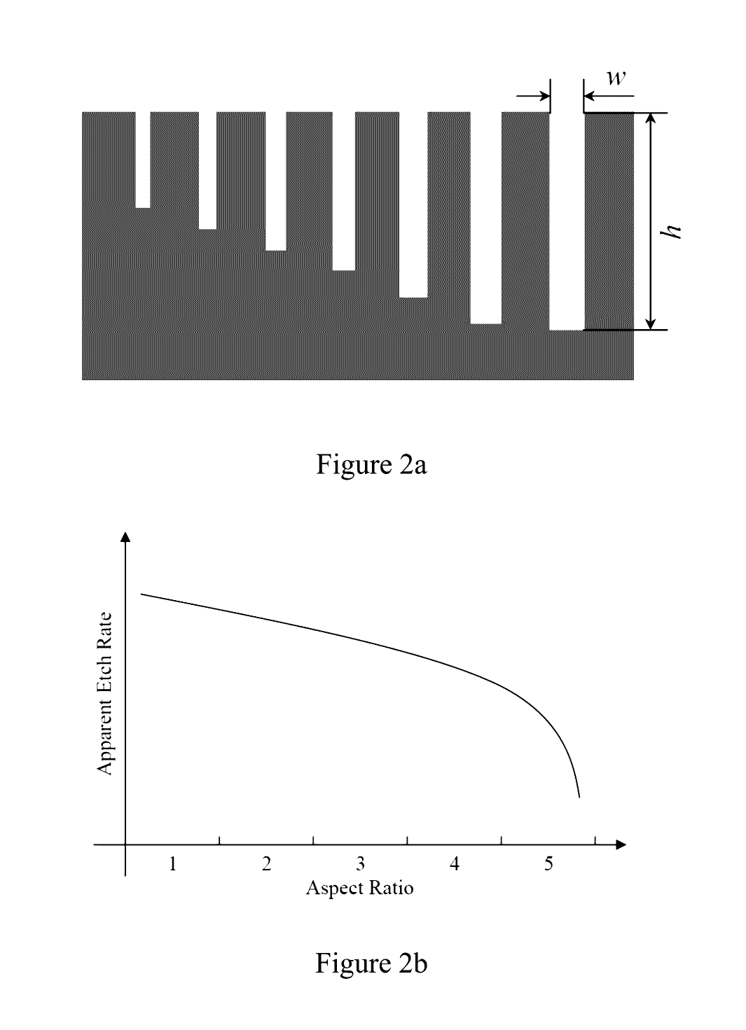

Referring to FIG. 2a, an illustrative example is of the mechanisms of aspect ratio dependent etching (ARDE). The aspect ratio dependent etching (ARDE), refers to the phenomenon whereby the etch rate scales not with absolute feature sizes, but rather with the aspect ratio. Generally, increasing aspect ratio decreases etch rate, which is caused by reduced transport of reactive species in deep and narrow structures.

As shown in FIG. 2a, the effect of ARDE is demonstrated and FIG. 2b illustrated the etching rate versus aspect ratio. It has been shown that this phenomenon is especially significant when a feature has a size in the range of from 0.4 to 20 μm, whereby the etching rate differs by about 40%. Thus, as will be understood, micro trenches having wide notches have higher etching rate than that of narrow notches.

In addition to ARDE, effects of the phenomena of micro loading effect has to be taken into consideration during fabrication of multi level components. As is known in the art, loading effect is a known phenomenon derived from non-uniform plasma distribution, non-vertical pattern profile of soft and hard masks, and various pattern densities. Loading effect may be categorized into micro loading and macro loading effect. Micro loading effect predominantly causes an etching rate decrease with increasing local pattern density. High pattern density areas have higher etchant consumption, and as the transport of etchants across an article or material to be etched is limited by gas diffusion.

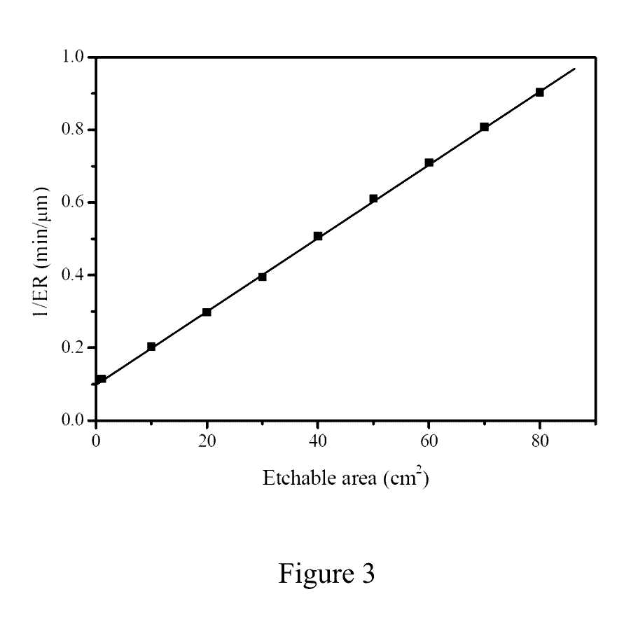

As shown in FIG. 3, it is shown how etching rate varies with etchable area. Concentration variations may be sustained over a certain length scale, or for a certain depletion radius. This leads to etchant deficits and decreased etching rate in high pattern density areas.

In comparison with to ARDE, micro loading effect is relatively small yet not inevitable, and this effect may be decreased by techniques including increasing the gas flow rate or decreasing the pressure in an etching process.

When etching a material in accordance with the present invention, the size of etched recesses are typically of a dot form and the spacing therebetween adjacent dots may be determined and selected depending upon the requirements and demand of an article or material to be formed.

The size of such recess are preferably utilised should not be overly small so as to avoid severe diffraction during photolithography process and also so as to reduce the possibility or likelihood of defects of micro pillars or rod portions formed.

According to diffraction theory, the dot size utilised should typically be greater than ten times of the wavelength of the UV light source used in photolithography, which is about 4 μm.

The spacing of adjacent dots should also be provided in accordance with diffraction theory, such that the spacing should also be larger than 4 μm. However as will be appreciated by those skilled in the art, such parameters are not necessarily an absolute parameter for compliance therewith, for applications such as when the shape of a pillar is not of particular importance to an article or material to which the process is to be applied, depending upon the particulars of the application. By suitable selection and design of different spacing of the dots or trench width, a silicon component with different trench depth may be achieved by utilisation of DRIE techniques.

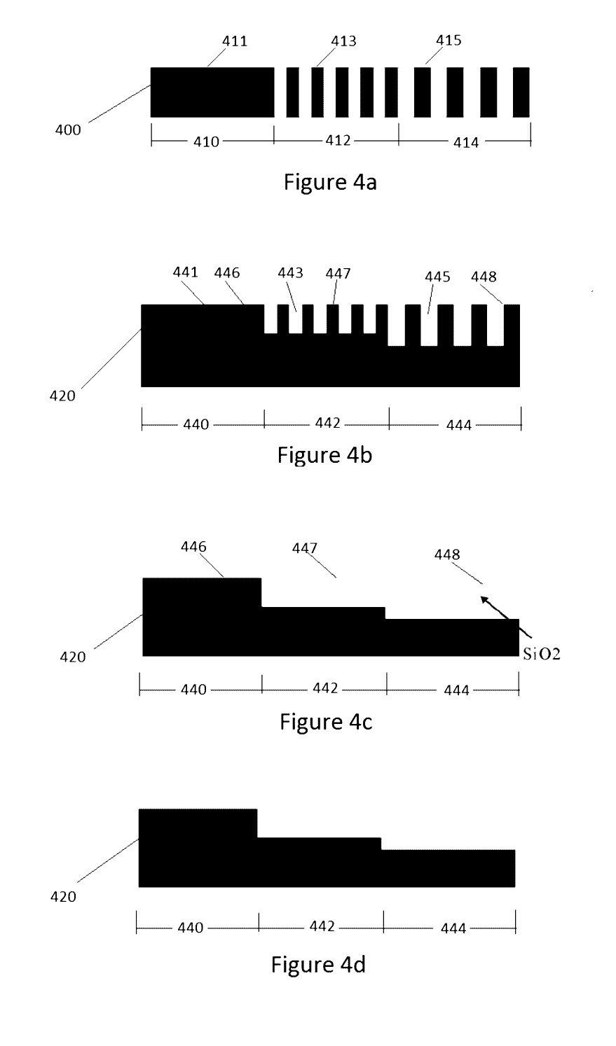

Referring to FIG. 4a-4d, there is shown a schematic illustrative representation and description of a fabrication process of an article of three levels, in accordance with the present invention, whereby the process is described in reference to a component formed form silicon.

As shown and represented in FIG. 4a, a top view schematic representation of a mask 400 to be utilised in order to provide a multi-level component is depicted having a requisite pattern in order to allow the formation of a multi-level component in accordance with the process of the present invention.

The mask 400 is divided into three portions 410, 412 and 414, in which the pattern density selected is about 50%. The displacement of the gaps between each trench 411, 413 and 415 of three portions 410, 412 and 414 as utilised are 1 μm, 2 μm and 3 μm, respectively. In common UV lithography systems, the critical dimension is 0.4 μm, and in the following example the minimal pitch size was set to be 1 μm.

As shown by the side view schematic representation of FIG. 4b a component 420 or portion of a component formed from a silicon or silicon based material is depicted, which is represented as having been etched utilising ARDE in accordance with the present invention, by way of the mask of FIG. 4a.

As will be noted from this representation, due to the different aspect ratios as provided by the exemplary mask of FIG. 4a, and thus due to ARDE effect, the etching depth, by way of example from a DRIE process, results in a different etch effect along the component 420 each portion 440, 442 and 444 of the component 420.

As will be appreciated and as shown, the area containing wider trenches 415 of the mask 400 result in a deeper etching depth of a trench within the component 420 as shown in FIG. 4b, and such aspect ratio dependent etching phenomena is an established phenomena.

Upon completion of the etching process as described and as represented in FIG. 4b, there remain a plurality of micro trenches 441, 443 and 445 and a plurality of micro pillars 446, 447 and 448.

Following an etching process such as a DRIE etch of FIG. 4b, the micro pillars 446, 447 and 448 of the silicon component 420 are removed so as to provide as multi-layer component.

Referring to FIG. 4c as depicted schematically, the silicon component 420 is oxidized, which is typically within a furnace. Such an oxidation process consumes the micro pillars 446, 447 and 448 so as to form silicon oxide.

Following oxidation as depicted schematically, the pillars 446, 447 and 448 which have been consumed to as to be silicon oxide, which can be removed from the component 420 by dissolving the micro pillars 446, 447 and 448 in hydrogen fluoride (HF) solution.

Upon complete removal of the silicon micro pillars 446, 447 and 448 by oxidation and subsequent treatment in HF solution, a multi-level silicon component is obtained as depicted in FIG. 4d.

As will be appreciated by those skilled in the art, the present invention allows for the formation of multi-level components or components designing different patterns, it is able to fabricate multi-level components or having a continuous curved surface.

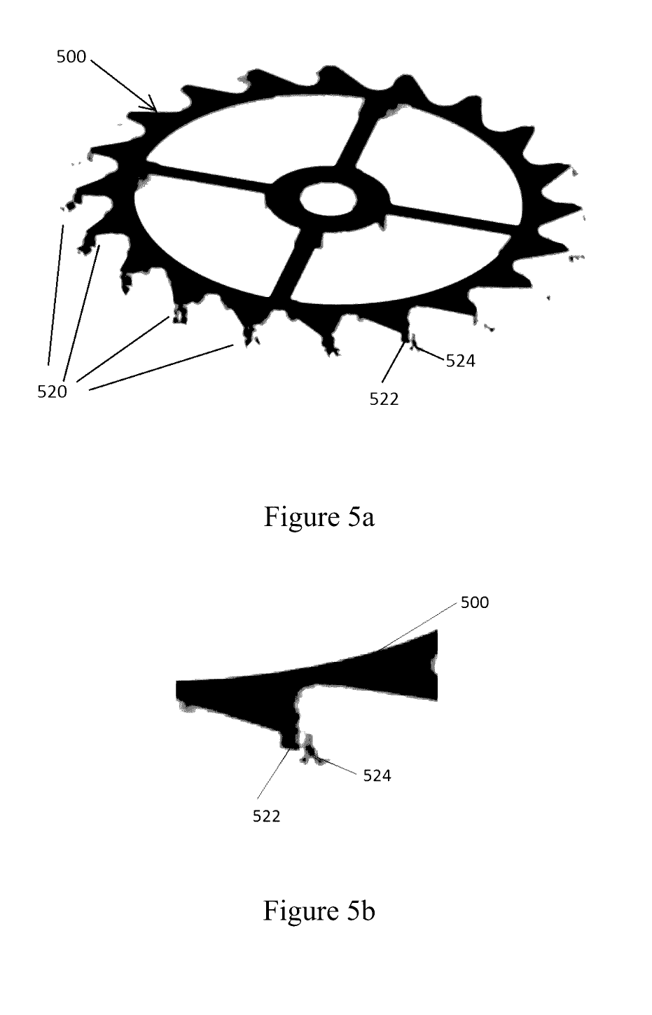

Referring to FIG. 5a, there is shown a photographic representation of a micro component 500 and in FIG. 5b an enlarged portion of the component 500 of FIG. 5a, in this case a small mechanical component as utilised in mechanical time pieces, which includes a plurality of multi-level portions 520 located at the outermost extremities of the micro component.

The exemplary embodiment as depicted, is a component formed from silicon, upon which the multi-level portions 520 have been formed in accordance with the method of the present invention, having multiple surfaces 522 and 524.

The present invention provides a process and product formed according thereto, whereby a multi-layers may be formed on the component without the necessity of multiple masking and multiple etching type processes.

Accordingly, the present invention provides for the manufacture of a component with dimensional accuracy, ease of manufacture, whilst obviating alignment issues as associated with processes of the prior art, such as optical manual alignment.

Greater dimensional accuracy as provided by the present invention, provides for the manufacture of components with enhanced tolerances as well as repeatability, provides for increased manufacturing efficiency, reduces disposal of non-compliant components, provides for ease of assembly, as well as reduces component wear, in particular for components engaged with other components or the like, due to increased component compliance, enhances component engagement and interoperability, as well as decreased unwanted eccentricity.

1.-34. (canceled)

35. A method of forming a multi-level component having a first surface portion of a first level and a second surface portion of a second level different from the level of the first level, said method including the steps of:
(i) forming at least one arrangement of micro trenches or an arrangement of micro pillars having a micro trench therebetween in a predetermined arrangement in a mask material by one or more lithography processes, wherein one or more of said micro trenches have a first aspect ratio and one or more of said micro trenches have a second aspect ratio different from said first aspect ratio;
(ii) applying one or more etching processes to a surface of a component upon which said mask is applied, wherein the component is etched by an aspect ratio dependent etch (ARDE) process so as to form an arrangement of micro trenches and micro pillars between adjacent micro trenches;
wherein one or more micro trenches corresponding to the micro trenches of the first aspect ratio is etched to a first level from said surface of the component, and,
wherein one or more micro trenches corresponding to the micro trenches of the second aspect ratio is etched to a second level from said surface of the component and at different level to said first level; and
(iii) removing said arrangement of micro pillars from said component by a removal process;
wherein upon removal of said micro pillars a first surface portion is formed at said first level and a second surface portion is formed at said second level, wherein the second surface portion is at a different level to that of the of the first surface portion.

36. The method according to claim 35, wherein said arrangement of micro trenches or arrangement of micro pillars having a micro trench therebetween includes a first plurality of micro trenches or micro pillars having a micro trench between adjacent micro pillars, and a second plurality of micro trenches or micro pillars having a micro trench between adjacent micro pillars, and
wherein the micro trenches of said first plurality of micro trenches or micro pillars have said first aspect ratio, and wherein the micro trenches of said second plurality of micro trenches or have said second aspect ratio; and wherein upon removal of said first plurality of micro pillars the first surface portion is formed at said first level and upon removal of said second plurality of micro pillars said second surface portion is formed.

37. The method according to claim 36, wherein the first surface portion and the second surface portion are discrete surface portions from each other and are formed in a non-continuous spatial arrangement with respect to each other.

38. The method according to claim 36, wherein said arrangement micro trenches or an arrangement of micro pillars includes a further plurality of micro trenches or micro pillars having a micro trench between adjacent micro pillars, and wherein upon removal of said further plurality of micro pillars a further surface portion is formed at a further level different from the level of the first surface portion and different from the level of the second surface portion.

39. The method according to claim 38, wherein the first surface portion, the second surface portion and the further surface portion are discrete surface portions from each other and are formed in a non-continuous spatial arrangement with respect to each other.

40. The method according to claim 35, wherein the first surface portion and the second surface portion are continuous surface portions and are formed in a continuous spatial arrangement with respect to each other.

41. The method according to claim 40, wherein a plurality of arrangements of micro trenches or an arrangement of micro pillars having a micro trench therebetween is formed, and wherein each of said plurality of micro trenches has a unique aspect ratio, such that a plurality of surface portions is formed in said component, and wherein said plurality of surface portions are formed in a continuous spatial arrangement with respect to each other and with first surface portion and with said second surface portion.

42. The method according to claim 41, wherein said plurality of surface portions and said first surface portion and said second surface portion collectively form a linear surface or collectively form a non-linear surface.

43. The method according to claim 35, wherein the width of said micro trenches of said first aspect ratio formed in said mask material is less than 10 μm, and wherein the width of micro trenches of said second aspect ratio formed in said mask material is less than 10 μm.

44. The method according to claim 35, wherein the lithography process is UV lithography, laser lithography, electron beam lithography, x-ray lithography, chemical lithography or a combination thereof.

45. The method according to claim 35, wherein the etching process is deep reactive ion etching (DRIE), reactive ion etching (RIE) or inductively coupled plasma (ICP) etching.

46. The method according to claim 35, wherein the mask is a photoresist, and the at least one arrangement of micro trenches or an arrangement of micro pillars having a micro trench therebetween in a predetermined arrangement is formed after application of the mask to the component.

47. The method according to claim 35, wherein the mask is a hard mask, and the and the at least one arrangement of micro trenches or an arrangement of micro pillars having a micro trench therebetween in a predetermined arrangement is formed in the mask prior to application of the mask to the component, and wherein the hard mask is formed from materials including oxidized silicon, or metal or metal allow based materials, polymeric materials, or the like.

48. The method according to claim 35, wherein the removal process for removal of said micro pillars from said component includes a thermal oxidation process including a dry oxygen process, a wet oxygen, or a combination thereof.

49. The method according to claim 35, wherein the removal of said micro pillars further includes applying a chemical etching process for removal of said micro pillars from said component.

50. The method according to claim 49, wherein the chemical etching process is a hydrogen fluoride (HF) treatment process, and wherein hydrogen fluoride (HF) treatment process is effected with a concentration in the range of from 1% to 49%.

51. The method according to claim 35, wherein the component is formed from a silicon or silicon-based material, or formed form a gemstone material including diamond, pearl, sapphire, synthetic sapphire or the like.

52. The method according to claim 49, wherein the component is formed from Gallium arsenide (GaAs), and wherein the chemical etching process is a Phosphoric acid (H₃PO₄) treatment process.

53. The method according to claim 35, wherein the component is a micro component, a mechanical device component or a mechanical timepiece component.

54. A multi-level component having first portion of a first level and a further portion of a further level different to the level of the first portion, wherein said multi-level component is formed according to a method of claim 35.

55. The multi-level component according to claim 54, wherein the multi-level component is a micro component, a mechanical device component, a mechanical timepiece component or a biomedical device component.

56. The multi-level component according to claim 54 wherein the component is formed from a silicon or silicon-based, or form a gemstone material including diamond, pearl, sapphire, synthetic sapphire or the like.
